(19) United States
(12) Patent Application Publication
(10) Pub. No.: US 2017/0293151 A1
(43) Pub. Date: Oct. 12, 2017

(54) 3D DISPLAY DEVICE

(71) Applicant: Wuhan China Star Optoelectronics Technology Co.Ltd, Wuhan City (CN)

(72) Inventor: Guowei Zha, Wuhan City (CN)

(21) Appl. No.: 15/107,926

(22) PCT Filed: Apr. 28, 2016
(86) PCT No.: PCT/CN2016/080450

§ 371 Date: Jun. 24, 2016

(30) Foreign Application Priority Data
Apr. 8, 2016 (CN) 201610217058.0

(51) Int. Cl. G02B 27/22; H01L 51/52; G02F 1/1335; H01L 27/32; G02F 1/29; G02F 1/1343

(52) U.S. Cl. CPC G02B 27/2214; G02F 1/29; G02F 1/13439; G02F 1/134309; G02F 1/133528; H01L 27/3232; H01L 51/5281; H01L 51/5275; G02F 2001/133548; G02F 2001/133302

(57) ABSTRACT

The present invention provides a 3D display device, and the 3D display device comprises a display panel (30), and a metal wire grid polarizer (20) and a liquid crystal lens (10) located above the display panel (30); the liquid crystal lens (10) comprises: a lens upper glass substrate (1), a lens lower glass substrate (5), which is oppositely located to the lens upper glass substrate (1), a common electrode (2) located on one side of the lens upper glass substrate (1) facing the lens lower glass substrate (5), a plurality of strip electrodes (4) which are in parallel spaced arrangement on one side of the lens lower glass substrate (5) facing the lens upper glass substrate (1), and a liquid crystal layer (3) located between the lens lower glass substrate (5) and the lens upper glass substrate (1).

### FIELD OF THE INVENTION

The present invention relates to a display technology field, and more particularly to a 3D display device.

### BACKGROUND OF THE INVENTION

While the digital audio and video technology enters the high resolution time, the Three Dimension (3D) stereoscopic display technology has been drawn the attention and favor of the people data by day. The naked eye 3D technology gets rid of the complicated accessory equipments and goes over big.

There are kinds of technologies to realize the naked eye 3D display, such as optical grating, liquid crystal lens,most of which at present is mainly based on spacialdivision of subpixels. Such method leads to the decreased 3D image resolution of the display panel in comparison with 2D panels. The 3D effect are totally far from perfection, suffering low image resolutions. Moreover, the adding 3D modules pose negative effect on the 2D display effect as well, which is totally unacceptable.

With the progress of the small size panel display technology, the resolution of the small size display panel of cellular phone and tablet is gradually raised, too. The high end technology of ultra resolution (3840*2160) display has entered the market. Thus, the resolution of the 3D image is also gradually raised to the Full High Definition (FHD) level. Meanwhile, the size of the Sub pixel is decreasing, to 60 micrometer, 50 micrometer, and even 40 micrometer and below.

As shown in FIG. 1, which is a 3D display device according to prior art, comprising: a display panel 100, a polarizer 200 located on the display panel 100, a liquid crystal lens 300 located on the polarizer 200. To realize the naked eye 3D display, the pixel P of the display panel 100 is required to be located on the focal plane of the liquid crystal lens 300. The calculation formula of the focal distance f is f=L*Wₚ/X, wherein L is the distance from the human eye to the 3D display device (watch distance), and Wₚ is the pixel pitch, and X is the distance between the two eyes (generally 65mm). The liquid crystal lens 300 is achieved by the liquid crystal structure located between two glass substrates. Because the watching distance of the mobile device is about 10 centimeter to 40 centimeter, and with the decreasing sub pixels size, the focal distance f will be less than 500 micrometer, and even below 200 micrometer. However, in the traditional naked eye 3D TV display based on the liquid crystal lens, the watching distance is comparatively much larger, and thus non-rigid requirements are posed on the focal distance f. It generally requires thicker glass substrate, and in some cases, a thicker glass is chosen for realizing such effect. When the liquid crystal lens is applied in the mobile device, the watching distance gets smaller, and the focal distance f gets smaller, accordingly. Thus, the distance between the pixel P and the liquid crystal lens needs to be decreased. Then, there will be higher requirement for thinner glass substrate; on the other hand, to realize the 3D display effect, an input light with extraordinary polarization (e light) to the liquid crystal lens 300 is a prerequisite and usually the polarizer 200 is placed on the display panel 100. Typically the polarizer 200 is an absorption type polarizer, composed of a protective layer, an adhesive layer and a polarizer layer. The total thickness is above 200 micrometer, which increases the distance between the pixel and the liquid crystal lens, and become a hurdle for realizing the high resolution naked eye 3D display.

The metal wire grid is a periodic structure composed of metal and dielectric layer, which can obviously pass the TM light (perpendicular with the metal wire alignment direction) and reflect the TE light (parallel with the metal wire alignment direction). And the extinction ratio is high enough as a polarizer. Therefore, it can act as an ideal polarizer. Because the thickness is merely the nanometer scale and the manufacture process has been mature gradually, it draws lots of attentions.

### SUMMARY OF THE INVENTION

An objective of the present invention is to provide a 3D display device, which can decrease a thickness of a polarizer and decrease a distance between a pixel and a liquid crystal lens in the 3D display device to realize high resolution naked eye 3D image display.

For realizing the aforesaid objective, the present invention provides a 3D display device, comprising a display panel, and a metal wire grid polarizer and a liquid crystal lens located above the display panel;

the liquid crystal lens comprises: a lens upper glass substrate, a lens lower glass substrate, which is oppositely located to the lens upper glass substrate, a common electrode located on one side of the lens upper glass substrate (facing the lens lower glass substrate), a plurality of strip electrodes which are in parallel spaced arrangement on one side of the lens lower glass substrate (facing the lens upper glass substrate), and a liquid crystal layer located between the lens lower glass substrate and the lens upper glass substrate;

the metal wire grid polarizer is located between the display panel and the plurality of strip electrodes.

The display panel is an OLED display panel, or a LCD display panel.

The metal wire grid polarizer is located on the display panel, and comprises: a dielectric layer located on the display panel, and a plurality of metal wires which are in parallel spaced arrangement on the dielectric layer.

The metal wire grid polarizer is located on one side (away from the lens upper glass substrate) of the lens lower glass substrate, and comprises: a plurality of metal wires which are in parallel spaced arrangement on one side away from the lens upper glass substrate of the lens lower glass substrate, and a dielectric layer located under the plurality of metal wires which are in parallel spaced arrangement and on the lens lower glass substrate.

The metal wire grid polarizer is between the lens lower glass substrate and stripe electrodes of the liquid crystal lens, and comprises: a plurality of metal wires which are in parallel spaced arrangement on one side away from the lens upper glass substrate of the lens lower glass substrate, and a dielectric layer located under the plurality of metal wires which are in parallel spaced arrangement and on the lens lower glass substrate, and a flat layer located on the plurality of metal wires, and the plurality of strip electrodes are located on the flat layer.

A period of the metal wire grid polarizer is from 20 nanometer to 500 nanometer, and a duty ratio is from 0.1 to 0.9.

Material of the metal wire grid polarizer is aluminum, silver or gold.

A length of a sub pixel in the display panel is smaller than 60 micrometer.

A width of the plurality of strip electrodes is 10 micrometer to 1000 micrometer.

Material of the dielectric layer is silicon dioxide, silicon monoxide, magnesium oxide, silicon nitride, titanium dioxide or tantalum pentoxide.

The present invention further provides a 3D display device, comprising a display panel, and a metal wire grid polarizer and a liquid crystal lens located above the display panel;

the liquid crystal lens comprises: a lens upper glass substrate, a lens lower glass substrate, which is oppositely located to the lens upper glass substrate, a common electrode located on one side of the lens upper glass substrate(facing the lens lower glass substrate), a plurality of strip electrodes which are in parallel spaced arrangement on one side of the lens lower glass substrate facing the lens upper glass substrate, and a liquid crystal layer located between the lens lower glass substrate and the lens upper glass substrate;

the metal wire grid polarizer is located between the display panel and the plurality of strip electrodes;

wherein the display panel is an OLED display panel, or a LCD display panel;

wherein the metal wire grid polarizer is located on the display panel, and comprises: a dielectric layer located on the display panel, and a plurality of metal wires which are in parallel spaced arrangement on the dielectric layer.

The benefits of the present invention are: the present invention provides a 3D display device, and the 3D display device comprises a display panel, and a metal wire grid polarizer and a liquid crystal lens located above the display panel. By utilizing the nanometer scale metal wire grid polarizer to replace the traditional absorption type polarizer, the polarized input light to the liquid crystal lens can be realized, and meanwhile, the thickness of the polarizer can be decreased so as to decrease the distance between the pixel and the liquid crystal lens in the 3D display device and to realize high resolution naked eye 3D image display.

### BRIEF DESCRIPTION OF THE DRAWINGS

In order to better understand the characteristics and technical aspect of the invention, please refer to the following detailed description of the present invention is concerned with the diagrams, however, provide reference to the accompanying drawings and description only and is not intended to be limiting of the invention.

In drawings,

FIG. 1 is a structure diagram of a 3D display device according to prior art;

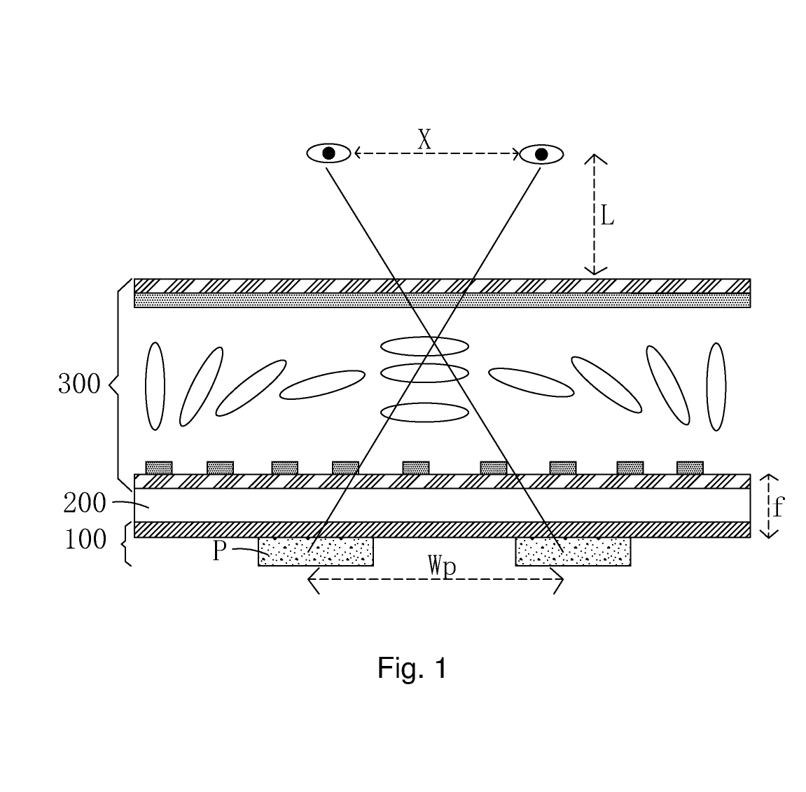

FIG. 2 is a structure diagram of the first embodiment of the 3D display device according to the present invention;

FIG. 3 is a structure diagram of the second embodiment of the 3D display device according to the present invention;

FIG. 4 is a structure diagram of the third embodiment of the 3D display device according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

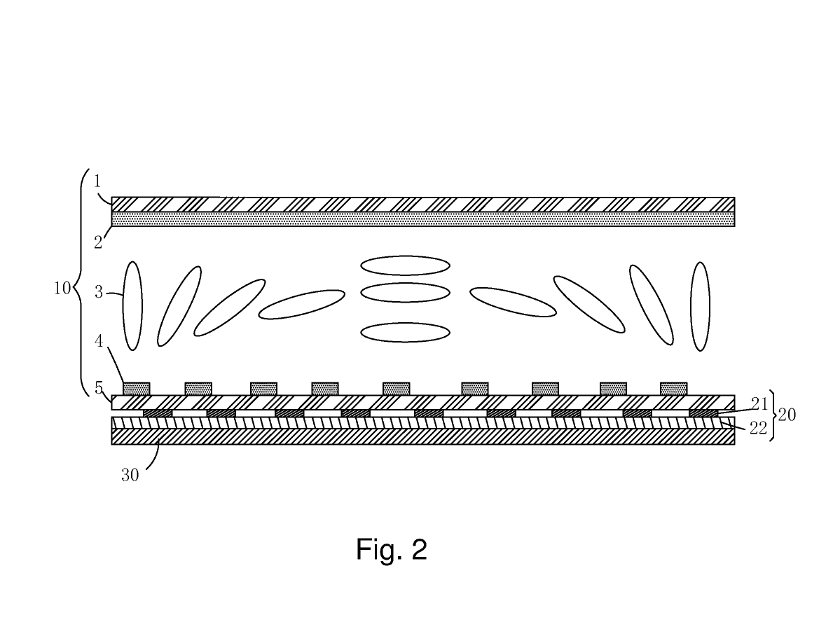

Please refer to FIG. 2. The 3D display device according to the first embodiment of the present invention, comprising a display panel 30, and a metal wire grid polarizer 20 and a liquid crystal lens 10 located above the display panel 30.

Specifically, the display panel 30 is a Liquid Crystal Display (LCD), or an Organic Light Emitting Display (OLED). A length of a sub pixel in the display panel 30 is smaller than 60 micrometer. The smaller the size of the sub pixel is, the higher the resolution of the display panel 30 is.

Specifically, the liquid crystal lens 10 comprises: a lens upper glass substrate 1, a lens lower glass substrate 5, which is oppositely located to the lens upper glass substrate 1, a common electrode 2 located on one side of the lens upper glass substrate 1 facing the lens lower glass substrate 5, a plurality of strip electrodes 4 which are in parallel spaced arrangement on one side of the lens lower glass substrate 5 facing the lens upper glass substrate 1, and a liquid crystal layer 3 located between the lens lower glass substrate 5 and the lens upper glass substrate 1.

Furthermore, the common electrode 2 is a one piece plate electrode. As selecting the liquid crystal molecules in the liquid crystal layer 3, the liquid crystal molecules, of which the refractivity of the e light and the normal light (o light) is higher, are preferred for convenience to decrease the thickness of the liquid crystal lens. The liquid crystal lens further comprises an alignment layer on one side of the lens lower glass substrate 5 facing the liquid crystal layer 3. The width and gap of the plurality of strip electrodes 4 can be equal or can be not equal. The specific width selected range is 10-1000 μm.

Specifically, the metal wire grid polarizer 20 can filter the light emitted by the display panel 30 to generate polarized light.

Specifically, the metal wire grid polarizer 20 is located at an arbitrary position between the display panel 30 and the plurality of strip electrodes 4. Selectably, in the first embodiment of the present invention, the metal wire grid polarizer 20 is located on the display panel 30, and comprises: a dielectric layer 22 located on the display panel 30, and a plurality of metal wires 21 which are in parallel spaced arrangement on the dielectric layer 22. Specifically, the metal wire grid polarizer 20 is located on the illuminating surface of the display panel 30, such as on the glass substrate on the LCD display panel.

Specifically, the working process of the 3D display device is: the display penal 30 emits light. The light is filtered by the metal wire grid polarizer 20 to form a polarized light. The polarized light enters the liquid crystal lens from the lower part of the lens lower glass substrate 5 of the liquid crystal lens, and the voltages are applied to the strip electrodes 4 and the common electrode 2 to twist the liquid crystal molecules in the liquid crystal layer 3, wherein the voltage of the strip electrodes 4 at the border is higher, and the voltage of the strip electrodes 4 in the middle is lower. The refractivity of the liquid crystal layer 3 gradually decreases from the middle to the border to form the lens effect. The variation of the refractivity makes the aforesaid polarized light be focused to a predetermined direction as penetrating through the liquid crystal layer 3 to realize the 3D image display.

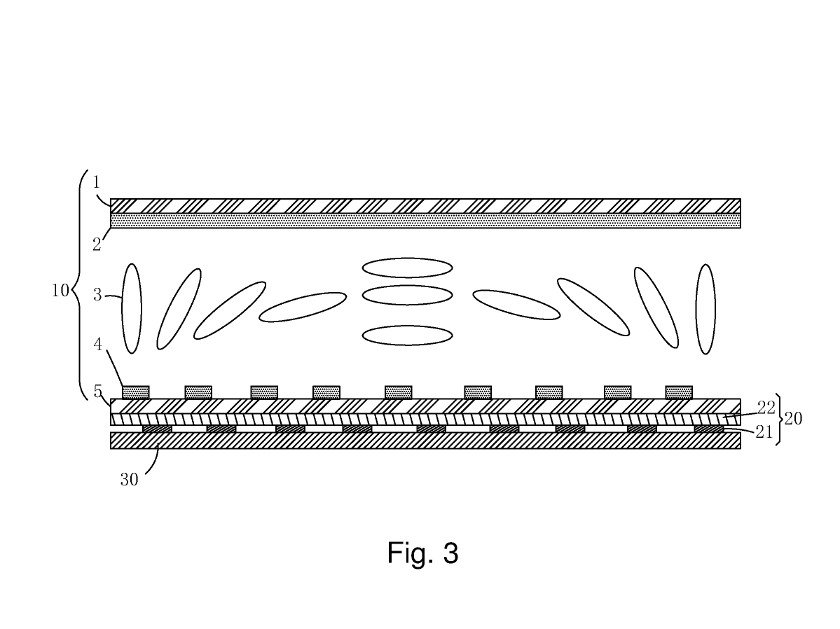

Selectably, referring to FIG. 3, in the second embodiment of the present invention, the metal wire grid polarizer 20 is located on one side of the lens lower glass substrate 5 away from the lens upper glass substrate 1, and comprises: a plurality of metal wires 21 which are in parallel spaced arrangement on one side of the lens lower glass substrate 5 away from the lens upper glass substrate 1, and a dielectric layer 22 located between the plurality of metal wires 21 which are in parallel spaced arrangement and the lens lower glass substrate 5.

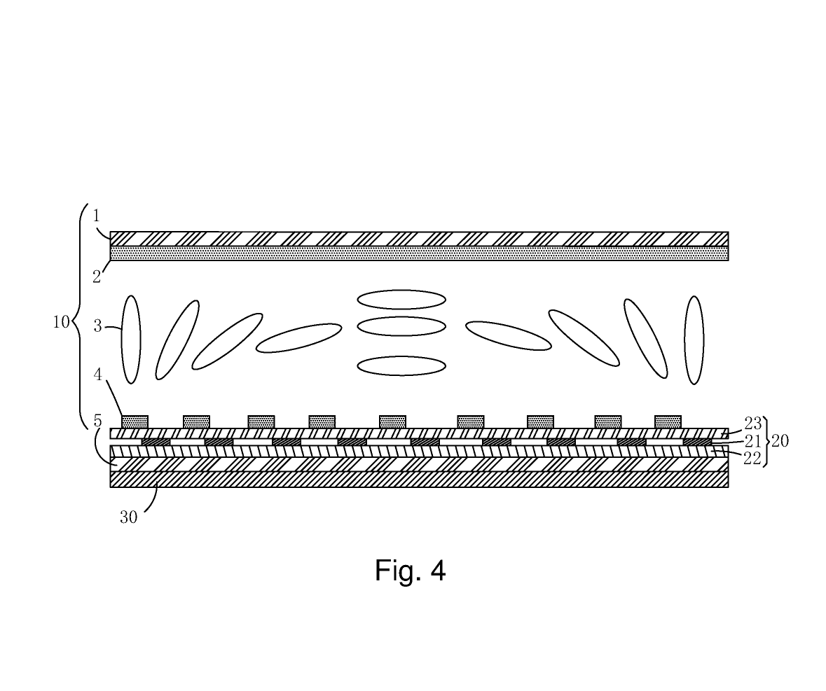

Selectably, referring to FIG. 4, in the third embodiment of the present invention, the metal wire grid polarizer 20 is between the lens lower glass substrate 5 and stripe electrodes of the liquid crystal lens, and comprises: a plurality of metal wires 21 which are in parallel spaced arrangement on one side of the lens lower glass substrate 5 facing the lens upper glass substrate 1, and a dielectric layer 22 located between the plurality of metal wires 21 which are in parallel spaced arrangement and the lens lower glass substrate 5, and a flat layer 23 located on the plurality of metal wires 21, and the plurality of strip electrodes 4 are located on the flat layer 23.

Specifically, the material of the metal wire grid polarizer 20 requires the larger imaginary part of refractivity. Preferably, the material of the metal wire grid polarizer 20 is aluminum (Al), silver (Ag) or gold (Au). Material of the dielectric layer 22 is silicon dioxide (SiO₂), silicon monoxide (SiO), magnesium oxide (MgO), silicon nitride (Si₃N₄), titanium dioxide (TiO₂) or tantalum pentoxide (Ta₂O₅).

Furthermore, the polarization of the metal wire grid polarizer 20 is due to the asymmetry as the TM light and the TE light pass through the metal wire grid polarizer 20. The TM light of which the polarization direction is perpendicular with the extension direction of the metal wires 21 can pass, and the TE light of which the polarization direction is parallel with the extension direction of the metal wires 21 will be reflected, and the polarization property and the effective wavelength band of the metal wire grid polarizer 20 can be determined by changing the structure parameters of the metal wire grid polarizer 20, i.e. by adjusting the period and the duty ratio of the metal wire grid polarizer 20, wherein the period of the metal wire grid polarizer 20 means the distance between the left side and the left side of the adjacent metal wires 21, and the duty ratio is the ratio of the width and the period of the metal wires 21. Preferably, the period of the metal wire grid polarizer 20 is from 20 nanometer to 500 nanometer, and the duty ratio is from 0.1 to 0.9.

The nanometer scale metal wire grid polarizer 20 is employed to replace the traditional micrometer scale, thick absorption type polarizer and is located between the display panel 30 and the liquid crystal lens 10, which can decrease thickness of the polarizer to decrease the distance between the pixel and the liquid crystal lens in the 3D display device to realize high resolution naked eye 3D image display. The technical problem that the focus of the liquid crystal lens becomes small due to the dimension shrinkage of the pixel P can be overcame. At present, the manufacture process of the smaller size metal wire grid polarizer has already been pretty mature, and the mass production is possible. Therefore, the present invention is particularly suitable for the small size 3D display device. Namely, the advantage for the application in the mobile display field is obvious.

In conclusion, the present invention provides a 3D display device, and the 3D display device comprises a display panel, and a metal wire grid polarizer and a liquid crystal lens located above the display panel. By utilizing the nanometer scale metal wire grid polarizer to replace the traditional absorption type polarizer, the polarized input light to the liquid crystal lens can be realized, and meanwhile, the thickness of the polarizer can be decreased so as to decrease the distance between the pixel and the liquid crystal lens in the 3D display device and to realize high resolution naked eye 3D image display.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A 3D display device, comprising a display panel, and a metal wire grid polarizer and a liquid crystal lens located above the display panel;
the liquid crystal lens comprises: a lens upper glass substrate, a lens lower glass substrate, which is oppositely located to the lens upper glass substrate, a common electrode located on one side of the lens upper glass substrate facing the lens lower glass substrate, a plurality of strip electrodes which are in parallel spaced arrangement on one side of the lens lower glass substrate facing the lens upper glass substrate, and a liquid crystal layer located between the lens lower glass substrate and the lens upper glass substrate;
the metal wire grid polarizer is located between the display panel and the plurality of strip electrodes.

2. The 3D display device according to claim 1, wherein the display panel is an OLED display panel, or a LCD display panel.

3. The 3D display device according to claim 1, wherein the metal wire grid polarizer is located on the display panel, and comprises: a dielectric layer located on the display panel, and a plurality of metal wires which are in parallel spaced arrangement on the dielectric layer.

4. The 3D display device according to claim 1, wherein the metal wire grid polarizer is located on one side away from the lens upper glass substrate of the lens lower glass substrate, and comprises: a plurality of metal wires which are in parallel spaced arrangement on one side away from the lens upper glass substrate of the lens lower glass substrate, and a dielectric layer located under the plurality of metal wires which are in parallel spaced arrangement and on the lens lower glass substrate.

5. The 3D display device according to claim 1, wherein the metal wire grid polarizer is between the lens lower glass substrate and stripe electrodes of the liquid crystal lens, and comprises: a plurality of metal wires which are in parallel spaced arrangement on one side away from the lens upper glass substrate of the lens lower glass substrate, and a dielectric layer located under the plurality of metal wires which are in parallel spaced arrangement and on the lens lower glass substrate, and a flat layer located on the plurality of metal wires, and the plurality of strip electrodes are located on the flat layer.

6. The 3D display device according to claim 1, wherein a period of the metal wire grid polarizer is from 20 nanometer to 500 nanometer, and a duty ratio is from 0.1 to 0.9.

7. The 3D display device according to claim 1, wherein material of the metal wire grid polarizer is aluminum, silver or gold.

8. The 3D display device according to claim 1, wherein a length of a sub pixel in the display panel is smaller than 60 micrometer.

9. The 3D display device according to claim 1, wherein a width of the plurality of strip electrodes is 10 micrometer to 1000 micrometer.

10. The 3D display device according to claim 3, wherein material of the dielectric layer is silicon dioxide, silicon monoxide, magnesium oxide, silicon nitride, titanium dioxide or tantalum pentoxide.

11. A 3D display device, comprising a display panel, and a metal wire grid polarizer and a liquid crystal lens located above the display panel;
the liquid crystal lens comprises: a lens upper glass substrate, a lens lower glass substrate, which is oppositely located to the lens upper glass substrate, a common electrode located on one side of the lens upper glass substrate facing the lens lower glass substrate, a plurality of strip electrodes which are in parallel spaced arrangement on one side of the lens lower glass substrate facing the lens upper glass substrate, and a liquid crystal layer located between the lens lower glass substrate and the lens upper glass substrate;
the metal wire grid polarizer is located between the display panel and the plurality of strip electrodes;
wherein the display panel is an OLED display panel, or a LCD display panel;
wherein the metal wire grid polarizer is located on the display panel, and comprises: a dielectric layer located on the display panel, and a plurality of metal wires which are in parallel spaced arrangement on the dielectric layer.

12. The 3D display device according to claim 11, wherein a period of the metal wire grid polarizer is from 20 nanometer to 500 nanometer, and a duty ratio is from 0.1 to 0.9.

13. The 3D display device according to claim 11, wherein material of the metal wire grid polarizer is aluminum, silver or gold.

14. The 3D display device according to claim 11, wherein a length of a sub pixel in the display panel is smaller than 60 micrometer.

15. The 3D display device according to claim 11, wherein a width of the plurality of strip electrodes is 10 micrometer to 1000 micrometer.

16. The 3D display device according to claim 11, wherein material of the dielectric layer is silicon dioxide, silicon monoxide, magnesium oxide, silicon nitride, titanium dioxide or tantalum pentoxide.
